(19) United States
(12) Patent Application Publication
(10) Pub. No.: US 2021/0116477 A1
(43) Pub. Date: Apr. 22, 2021

(54) Corded Probe with Interface

(71) Applicant: Tegam, Inc., Geneva, OH (US)

(72) Inventors: Andrew S. Brush, Chardon, OH (US); Adam R. Fleder, Concord, OH (US); James Newton, Geneva, OH (US); Anthony Schommer, III, Jefferson, OH (US); Russell House, Hudson, OH (US); Sanjay Kasam, Geneva, OH (US)

(73) Assignee: Tegam, Inc., Geneva, OH (US)

(21) Appl. No.: 16/658,272

(22) Filed: Oct. 21, 2019

(51) Int. Cl. G01R 1/067; G01R 15/09; G01R 1/04; G01R 15/12; G01R 19/25; G01R 19/155

(52) U.S. Cl. CPC G01R 1/06788; G01R 15/09; G01R 19/155; G01R 15/125; G01R 19/2503; G01R 1/04

(57) ABSTRACT

A probe for use with a measuring instrument. The probe is a wired probe assembly comprising a housing with an integrated user interface. The wired probe assembly further comprises a measuring component for contacting a device to be measured and a cord component connecting the measuring component to the measuring instrument. The user interface can indicate a status of an electrical parameter and allow an operator to provide inputs remotely to the measuring device.

### FIELD OF THE INVENTION

The present invention pertains generally to a corded probe for use with a measuring device that allows a user to simultaneously observe the status of a measured electrical property and provide control inputs remote from the measuring device while taking measurements in locations that may be difficult to reach and methods of using the same.

### BACKGROUND OF THE INVENTION

Metering instruments, such as multimeters, volt meters, bond meters, thermometers, and the like, are useful for measuring electrical properties such as current, resistance, impedance, continuity, and temperature. When using measurement instrumentation for servicing or maintaining equipment, there are often situations where the location of the desired measurement is difficult to reach. There are also situations where it is difficult for the technician to reach the measuring location while simultaneously observing the instrument display to ascertain the desired reading. Conventional measuring instruments utilize often use probes attached to the metering device, but the display or other indicators are located on the metering device itself. If the technician is in an environment where the display is not easily accessible, it may not be possible to determine readings in real time.

When making probed measurements using corded probes, such as required when measuring resistance and impedance, there is a need to provide some control input to the measuring instrument, for example, hold the reading, send the reading to a remote database, etc. When the probe operator is working in a confined space, access to the panel controls of the measuring instrument are often limited, and the operator may not be able to easily reach a control input on the instrument. The operator typically has to blindly try to keep the probe in contact with the electrical contacts and turn back to the measuring instrument to make control inputs leading to inaccurate readings.

Further, certain status or alarm indications such as “measurement good”, “reading outside normal limits”, “broken wire”' etc., are valuable information to the probe operator. These indications are normally presented by means of lamps located on the measuring instrument front panel, which will not be visible to the operator when they are remote-probing in a confined space. Once again, the operator must blindly try to keep the probe in contact with the electrical contacts and turn back to the measuring instrument to observe status or alarm indications of the device being tested.

Therefore, there is a long felt need in the art for a device with a display and input devices integrated into a probe that provides critical information at the measuring point. Further, there is a long-felt need in the art for a system for remotely observing the status of a measurable electrical property. There is also a need for a method of remotely controlling input to the measuring instrument while measuring the status of an electrical property.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some concepts in a simplified form as a prelude to the more detailed description that is presented later.

The present invention describes a probe for use with a measuring device. The measuring device is configured to measure electrical properties. The probe comprises a housing comprising a user interface element. The probe further comprises a measuring component extending from one end of the housing. The probe further comprises a cord component extending from the other end of the housing in electrical communication with the measuring component and the measuring instrument. The user interface component is configured to indicate the status of an electrical property of an item being measured.

The probe further comprises a display integrated into the housing that indicates a status of an electrical property being measured. The user interface component comprises at least one input element to communicate control inputs to the measuring instrument. The user interface component further comprises at least one indicating element for indicating a status of a measured electrical property,

In an additional embodiment, a system for remotely observing a status of a measured electrical property with a wired probe assembly comprises connecting the wired probe assembly to a measuring instrument. Then, the wired probe assembly is placed in electrical communication with a device to be tested. The status of the electrical property is tested by the measuring instrument, and the status is indicated on a display element of the wired probe assembly on the wired probe assembly remote from the metering device.

In an additional embodiment, a method of controlling input to a measuring device using a wired probe assembly comprises connecting the wired probe assembly to a measuring instrument. Then, the wired probe assembly is placed in electrical communication with a device to be tested. An operator uses an input element of the wired probe assembly to remotely send a control input to the measuring instrument, and the status of an electrical property in the device being tested is measured by the measuring instrument. The status of the measured electrical property is then indicated on a display element of the wired probe assembly.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and is intended to include all such aspects and their equivalents. Other advantages and novel features will become apparent from the following detailed description when considered in conjunction with the drawings.

### BRIEF DESCRIPTION OF THE FIGURES

While the specification concludes with claims particularly pointing out and distinctly claiming the present invention, it is believed that the present invention will be better understood from the following description in conjunction with the accompanying Figures, in which like reference numerals identify like elements, and wherein:

FIG. 1 illustrates a perspective view of a probe for use with a measuring instrument view of the present invention;

FIG. 2 illustrates a perspective view of the probe connected to the measuring instrument view of the present invention;

FIG. 3 illustrates a cut away perspective view of the probe for use with a measuring instrument view of the present invention;

FIG. 4 illustrates a cut away side view of the probe for use with a measuring instrument view of the present invention.

### DETAILED DESCRIPTION

In the following detailed description of the preferred embodiment, reference is made to the accompanying drawings that form a part hereof, and in which is shown by way of illustration, and not by way of limitation, a specific preferred embodiment in which the invention may be practiced. It is to be understood that other embodiments may be utilized and that changes may be made without departing from the spirit and scope of the present invention.

The present invention describes a wired probe assembly for use with a measuring instrument. The measuring instrument may be any instrument configured to generate or measure an electrical property, such as, but not limited to, multimeters, volt meters, bond meters, thermometers, continuity testers, humidity meters, and the like in a device having an unknown electrical status to be measured. Measurable electrical properties or parameters may include, electrical current, voltage, resistance, power, capacitance, inductance, temperature, and the like. The wired probe assembly is configured to allow an operator to take measurements in difficult to reach or remote areas while simultaneously observing a status of the measured electrical property in real time when the operator cannot see a display of the measuring instrument. Additionally, the operator can provide inputs to the measuring device remotely via the wired probe assembly. The present invention and method of use is more flexible, effective, and user friendly than existing devices.

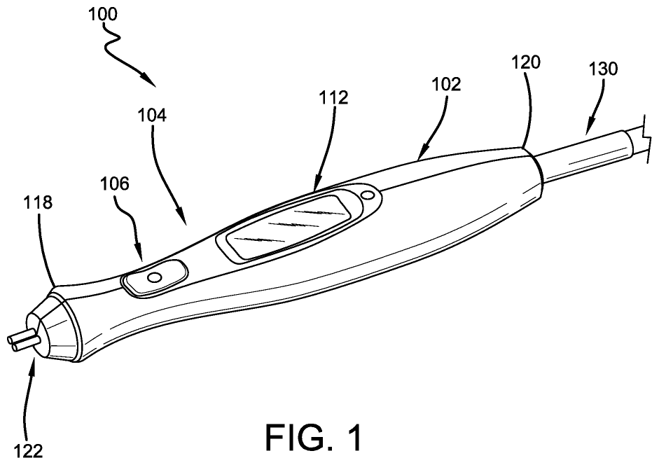

Referring initially to the drawings, FIGS. 1-4 illustrate a probe 100 for use with a measuring instrument 10. The measuring instrument 10 is used to measure an electrical parameter or property. The probe 100 is a wired probe assembly. The probe 100 comprises a housing 102 and a measuring component 122 extending from the housing 102. The probe 100 further comprises a cord component 130. The measuring component 122 extends from a first end 118 of the housing 102 and the cord component 130 extends out from a second end 120 of the housing. The cord component 130 is in electrical communication with both the measuring component 122 and the measuring instrument 10.

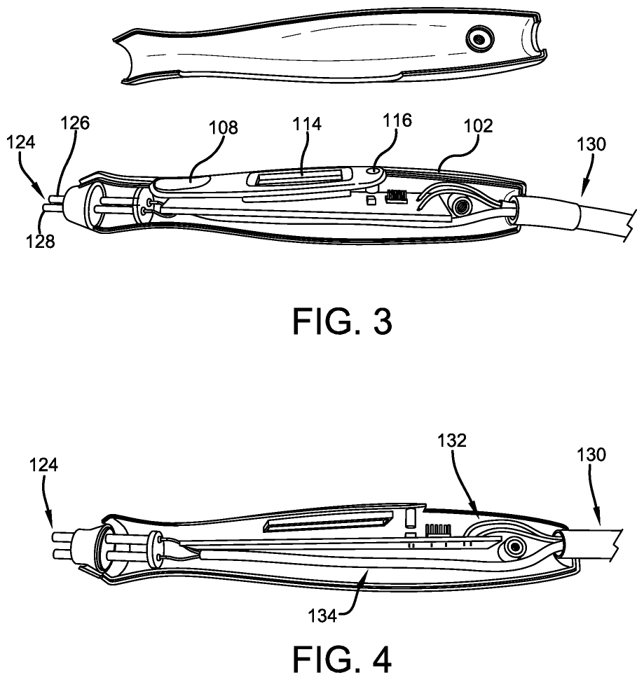

As illustrated in FIG. 1, the housing 102 comprises a user interface component 104. The user interface component 104 is configured to indicate a status of an electrical property of an item or device being measured. The user interface component 104 comprises at least one indicating element 112 or output. As illustrated in FIG. 3, the at least one indication element 112 comprises a display element 114, such as a digital or OLED screen. The display element 114 is used to display the status of the measured electrical property at a point of measurement that can be remote from the measuring instrument 10. The display element 114 is integrated into the housing 102 between the first end 118 and the second end 120. The display element 114 is in electrical communication with the measuring instrument 10 via the cord component 130 and is configured to receive a signal from the measuring instrument 10.

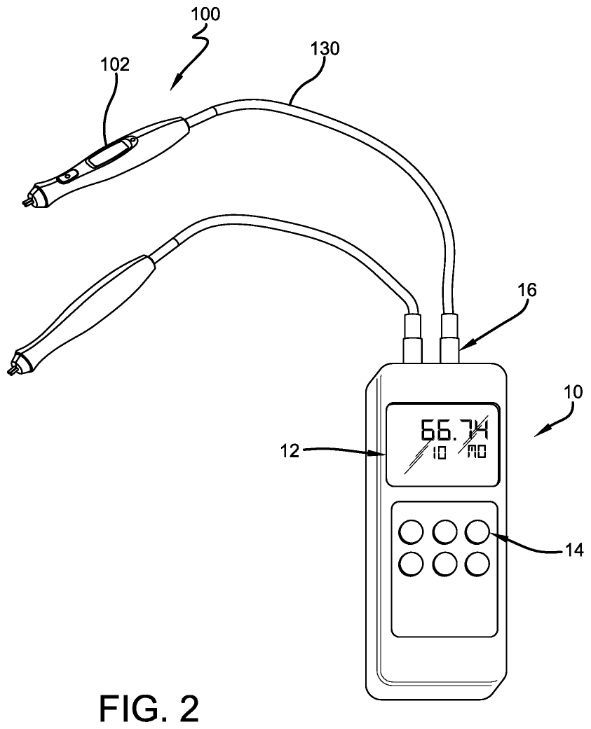

As illustrated in FIG. 2, the measuring instrument 10 may comprise a display 12, a plurality of control inputs 14, and a plurality of outputs 16. The cord component 130 of the probe 100 connects to the measuring instrument 10 via one of the plurality of outputs 16. While the status of the measured electrical property may be visible on the display 12 of the measuring instrument 10, the status of the measured property or a subset of the information is also transmitted to the display element 114 of the probe 100. As such the display element 114 can indicate the status of the electrical property at a remote measuring point from the measuring device 10.

Returning to FIG. 3, the at least one indicating element 112 may further comprise a visual indicator 116 integrated into the housing 102. The visual indicator 116 is typically at least one lamp, such as a LED. This is desirable as similar visual indicators that may be located on the measuring instrument 10 may not be visible to the operator when working in a remote or confined space. The visual indicator 116 incorporates one or more lamps, or similar devices, capable of indicating in one or more colors or by flashing that a state or condition of interest has occurred in the device being measured. As such, the visual indicator 116 is configured to indicate the status or the electrical property by flashing, illuminating, or by color.

As illustrated in FIGS. 1 and 3, the user interface component 104 further comprises at least one input element 106. The at least one input element 106 is configured to send a plurality of inputs to the measuring instrument 10 via the cord component 130 from the point of measurement. This allows the operator to provide some control input to the measuring instrument 10 when in a position where the control inputs 14 of the measuring instrument 10 are not readily accessible. The at least one input element 106 is typically a button 108, a control wheel, a joystick, or the like that is integrated into the user interface component 104 in the housing 102, that is capable of sending control inputs to the measuring instrument 10.

As illustrated in FIGS. 3 and 4, the measuring component 122 comprises a measuring input 124. The measuring input 124 may comprise a detection contact 126 and a reference contact 128. The measuring input 124 may be configured as a single contact pin as illustrated in FIG. 4 where the pin has a spring-loaded center pin for voltage detection, with an outer pin for the reference current. FIG. 3 illustrates the measuring input 124 configured as dual contact pins where one is the detection contact 126 and the other is the reference contact 128. However, these configurations are not meant as a limitation as the measuring input 124 may be configured with alligator type connectors (not shown), or any other type of measuring input as is known in the art.

The cord component 130 is used to connect the measuring component 122 to the user interface component 104 and the measuring instrument 10. The cord component 130 comprises a user interface control element 132 and a measuring signal element 134. The user interface control element 132 is typically a plurality of wires for communication and power that connect the user interface component 104 to the measuring instrument 10. The measuring signal element 134 is typically a plurality of wires that electrically connect the measuring input 124 to the measuring instrument 10. The measuring instrument 10 then receives signals from the measuring input 124 via the measuring signal element 134 and determines a measurement, then uses the user interface control element 132 to transmit the information to the display element 114 and the visual indicator 114 at the point of measurement. The operator may provide inputs to the measuring instrument 10 using the at least one input element 106 to transmit a signal via the user interface control element 132.

In another embodiment, a system for remotely observing a status of a measured electrical property using the wired probe assembly 100 comprises connecting the wired probe assembly 100 to the measuring instrument 10. Then the measuring component 122 of the probe 100 is placed in electrical communication with a device having an unknown electrical status to be tested via the measuring signal element 134 of the cord component 130. The status of the electrical property is measured by the measuring instrument 10 and transmitted back to the user interface component 104 of the probe 100 via the user interface control element 132 of the cord component 130. The status is then visually observable by the operator as it is indicated on the display element 114 or the visual indicator 116 of the at least one indicating element 112 of the user interface component 104 at a point of measurement remote from the measuring instrument 10.

In another embodiment, a method of remotely controlling input to the measuring instrument 10′using the wired probe assembly 100 comprises connecting the wired probe assembly 100 to the measuring instrument 10. Then the measuring component 122 of the probe 100 is placed in electrical communication with a device having an unknown electrical status to be tested via the measuring signal element 134 of the cord component 130. The at least one input element 106 is used to send a control input to the measuring instrument 10 via the user interface control element 132. The at least one input element 106 may comprise the control button 108 integrated into the housing 102 of the probe 100. Then the status of the electrical property is measured by the measuring instrument 10 and transmitted back to the user interface component 104 of the probe 100 via the user interface control element 132 of the cord component. The status is then visually observable by the operator as it is indicated on the display element 114 or the visual indicator 116 of the at least one indicating element 112 of the user interface component 104 at a point of measurement remote from the measuring instrument 10.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A probe for use with a measurement instrument comprising:
a housing comprising a user interface component;
a measuring component extending from the housing;
a cord component in electrical communication with the measuring component and the measuring instrument; and
wherein the user interface component is configured to indicate a status of an electrical property of an item being measured.

2. The probe of claim 1, wherein the user interface component comprises a display element integrated into the housing in electrical communication with the measurement instrument.

3. The probe of claim 2, wherein the display element is configured to receive a signal from the measuring instrument.

4. The probe of claim 2, wherein the display element indicates the status of the electrical property at a remote measuring point.

5. The probe of claim 1, wherein the user interface component comprises at least one input element.

6. The probe of claim 5, wherein the at least one input element is configured to send a plurality of control inputs to the measurement instrument.

7. The probe of claim 1, wherein the user interface component comprises at least one indicating element.

8. The probe of claim 7, wherein the at least one indicating element is a visual indicator.

9. The probe of claim 7, wherein the at least one indicating element indicates the status of the electrical property by flashing.

10. The probe of claim 7, wherein the at least one indicating element indicates the status of the electrical property via color.

11. The probe of claim 1, wherein the measuring component comprises a detection contact and a reference contact.

12. The probe of claim 1, wherein the measuring instrument is an ohm meter.

13. A system for remotely observing a status of a measured electrical property using a wired probe assembly comprising:
connecting the wired probe assembly to a measurement instrument;
placing the wired probe assembly in electrical communication of a device being tested;
measuring the status of the electrical property in the device being tested via the measuring instrument; and
transmitting the status of the measured electrical property to the wired probe assembly.

14. The system of claim 13, wherein the status is indicated visually on the wired probe assembly.

15. The system of claim 13, wherein the status is indicated on a display element of the wired probe assembly.

16. The system of claim 13, wherein the status is visible to a user at a point of measurement remote from the measurement instrument.

17. A method of remotely controlling input to a measuring instrument using a wired probe assembly comprising:
connecting the wired probe assembly to the measurement instrument;
placing the wired probe assembly in electrical communication of a device being tested;
using an input element of the wired probe assembly to send a control input to the measuring instrument; and
measuring a status of an electrical property in the device being tested via the measuring instrument.

18. The method of claim 17 further comprising the step of transmitting the status of the measured electrical property to the wired probe assembly.

19. The method of claim 17, wherein the input element is a control button integrated into the wired probe assembly.

20. The method of claim 17, wherein the status of the measured electrical property is indicated on a display element of the wired probe assembly.
